(19) United States
(12) Patent Application Publication
(10) Pub. No.: US 2025/0040441 A1
(43) Pub. Date: Jan. 30, 2025

(54) PIEZOELECTRIC VIBRATION DEVICE

(71) Applicant: DAISHINKU CORPORATION, Hyogo (JP)

(72) Inventors: Kazuya FUJINO, Hyogo (JP); Manabu OHNISHI, Hyogo (JP)

(73) Assignee: DAISHINKU CORPORATION, Hyogo (JP)

(21) Appl. No.: 18/693,648

(22) PCT Filed: Sep. 14, 2022
(86) PCT No.: PCT/JP2022/034441

§ 371 Date: Sep. 13, 2024

(30) Foreign Application Priority Data
Sep. 22, 2021 (JP) 2021-154811

(51) Int. Cl. H10N 30/88; H10N 30/20; H10N 30/80; H10N 30/87

(52) U.S. Cl. CPC H10N 30/883; H10N 30/2042; H10N 30/802; H10N 30/875

(57) ABSTRACT

A piezoelectric vibration device that can suppress deflection of a sealing member during molding using resin is provided. In a piezoelectric vibration device 1 including an oscillator 2 configured such that at least a vibrating portion 5 is sealed with a first sealing member 7 and a second sealing member 8 that are sealing members, an integrated circuit element 10 that is at least an electronic component element, a substrate 11 including a mounting surface 11a on which the oscillator 2 and the integrated circuit element 10 are mounted, and a molding portion 12 in which at least the oscillator 2 is covered with resin, the oscillator 2 includes a protecting member 9 that partially or entirely covers at least one of the first sealing member 7 and the second sealing member 8.

### TECHNICAL FIELD

The present invention relates to a piezoelectric vibration device.

### BACKGROUND ART

A piezoelectric vibration device includes, for example, a crystal oscillator using a crystal vibration piece. The crystal oscillator includes the crystal vibration piece that is a piezoelectric element, a holding member that holds the crystal vibration piece, and a lid member that seals the holding member. The crystal oscillator is configured such that the crystal vibration piece is held in the holding member having a box shape and formed of an insulator, such as ceramic. The crystal oscillator is sealed with the lid member such that an electrode of the crystal vibration piece and an electrode in the holding member are joined to each other.

The piezoelectric vibration device described above is expensive because the lid member formed of metal or glass is joined to the holding member formed of ceramic. The piezoelectric vibration device is configured such that the holding member having a box shape and the lid member are superimposed, so that the piezoelectric vibration device has an increased thickness. Therefore, there have been known piezoelectric vibration devices configured such that a vibrating portion including a first excitation electrode and a second excitation electrode, and a piezoelectric vibration plate connected to the vibrating portion via a connection portion and including an outer frame portion that surrounds the vibrating portion, are sealed with a sealing member. For example, Patent Document 1 describes a piezoelectric vibration device in which a sealing member formed of a resin film is joined to an outer frame portion having a larger thickness than a thickness of a vibrating portion to cover the vibrating portion.

### CITATION LIST

### Patent Document

Patent Document 1: Japanese Patent Application Publication No. 2020-141264

### SUMMARY OF INVENTION

### Technical Problem

In the piezoelectric vibration device described in Patent Document 1, at least the vibrating portion is covered by a resin member to protect the piezoelectric vibration device. In the piezoelectric vibration device having the configuration described in Patent Document 1, or a device obtained by combining an oscillator having a configuration in which a box-shaped holding member accommodating a piezoelectric vibration plate is sealed with a sealing member and an electronic component element, such as an integrated circuit element, together, in order to protect the crystal oscillator and the electronic component element from an external environment, these elements are covered by resin in some cases. Such a device is molded by resin in a closed mold. At this time, a molding pressure is applied to the piezoelectric vibration device from resin that is filled in the mold. Therefore, the sealing member is elastically deformed toward the vibrating portion by the molding pressure. Accordingly, there is a probability that, depending on a material and a thickness of the sealing member, a size of the outer frame portion of the piezoelectric vibration plate, and a magnitude of the molding pressure, the sealing member contacts the vibrating portion.

It is therefore an object of the present invention to provide a piezoelectric vibration device that can suppress deflection of a sealing member during molding using resin.

### Solution to Problem

The inventors of the present invention studied a piezoelectric vibration device capable of suppressing deflection of a sealing member during molding using resin. As a result of intensive studies, the inventors arrived at a configuration below.

A piezoelectric vibration device according to the present invention is a piezoelectric vibration device including an oscillator configured such that at least a vibrating portion is sealed with a sealing member, at least an electronic component element, a substrate including a mounting surface on which the oscillator and the electronic component element are mounted, and a molding portion in which at least the oscillator is covered with resin. The oscillator includes a protecting member that covers at least a portion of the sealing member.

In the configuration described above, in the oscillator sealed with the sealing member, at least a portion of the sealing member is covered by the protecting member. Resin that is filled in a mold does not contact the portion of the sealing member covered by the protecting member. Therefore, a molding pressure from the resin that is filled in the mold is not applied to the sealing member covered by the protecting member. Thus, deflection of the sealing member can be suppressed during molding using the resin.

In another aspect, the piezoelectric vibration device of the present invention preferably has the following configuration. The oscillator is configured into a stacked body with three or more layers, the stacked body including a piezoelectric vibration plate configured such that a frame portion and the vibrating portion arranged inside a frame of the frame portion are integrally molded and the sealing members each being joined to a corresponding one of one and the other one of principal surfaces of the frame portion in the piezoelectric vibration plate to close a corresponding one of an opening of the one of the principal surfaces and an opening of the other one of the principal surfaces. The oscillator is configured such that one of the sealing members that closes at least one of the opening of the one of the principal surfaces and the opening of the other one of the principal surfaces is partially or entirely covered by the protecting member.

In the configuration described above, the oscillator is configured such that at least a portion of the sealing member that closes the opening of the frame portion is covered by the protecting member. The molding pressure from the resin that is filled in the mold is applied to the protecting member that covers the sealing member. Therefore, with the sealing member at least partially covered by the protecting member, the sealing member has increased resistance to the molding pressure from the resin that is filled in the mold. Thus, deflection of the sealing member can be suppressed during molding using the resin.

In another aspect, the piezoelectric vibration device of the present invention preferably has the following configuration. The oscillator includes at least a piezoelectric element including the vibrating portion, a box-shaped holding member configured such that one of principal surfaces thereof is opened to form a frame portion, and the sealing member that closes an opening of the holding member that holds the piezoelectric element inside the frame portion, and the sealing member is partially or entirely covered by the protecting member.

In the configuration described above, the oscillator is configured such that at least a portion of the sealing member that closes the opening of the holding member is covered by the protecting member. The molding pressure from the resin that is filled in the mold is applied to the protecting member that covers the sealing member. Therefore, with the sealing member at least partially covered by the protecting member, the sealing member has increased resistance to the molding pressure from the resin that is filled in the mold. Thus, deflection of the sealing member can be suppressed during molding using the resin.

In another aspect, the piezoelectric vibration device of the present invention preferably has the following configuration. The oscillator is configured into a stacked body with three or more layers, the stacked body including a piezoelectric vibration plate configured such that the vibrating portion is integrally molded in the frame of the frame portion and the sealing members each being joined to a corresponding one of one and the other one of principal surfaces of the frame portion each having an opening in the piezoelectric vibration plate to close a corresponding one of the opening of the one of the principal surfaces and the opening of the other one of the principal surfaces, and at least the sealing member that closes the opening of the other one of the principal surfaces of the frame portion is partially or entirely covered by the protecting member.

In the configuration described above, the oscillator is configured as a stacked body having a three-layer structure in which both the openings in the piezoelectric vibration plate in which the vibrating portion is integrally molded in the frame of the frame portion. The sealing member of the oscillator has increased resistance to the molding pressure by the protecting member. Thus, deflection of the sealing member can be suppressed during molding using the resin. Therefore, even when a thickness of the oscillator in a stacked direction is suppressed by adjusting a thickness of the piezoelectric vibration plate, the vibrating portion and the sealing member do not contact each other.

In another aspect, the piezoelectric vibration device of the present invention preferably has the following configuration. The oscillator is configured such that a portion of the vibrating portion is connected to the frame portion via a connecting portion, and the sealing member is a resin film.

In the configuration described above, in the oscillator, the frame portion is covered by the resin film that is easily elastically deformed. Furthermore, in the oscillator, at least a portion of the sealing member that is a resin film that is easily elastically deformed is covered by the protecting member, so that resistance of the sealing member to the molding pressure from the resin that is filled in the mold is increased. Thus, deflection of the resin film can be suppressed during molding using the resin.

In another aspect, the piezoelectric vibration device of the present invention preferably has the following configuration. The oscillator includes a recessed portion in one or both of one and the other one of principal surfaces of the piezoelectric vibration plate, and the recessed portion serves as the vibrating portion.

In the configuration described above, in the piezoelectric vibration plate, the vibrating portion is configured of the recessed portion obtained by recessing a portion of one or both of the principal surfaces. Therefore, the vibration plate can be configured such that a thickness of the vibrating portion can be reduced, for example, in an AT-cut crystal plate. Moreover, in the oscillator including the above-described piezoelectric vibration plate, a portion of the sealing member that covers the recessed portion is covered by the protecting member, so that the resistance of the sealing member to the molding pressure from the resin that is filled in the mold is increased. Thus, deflection of the sealing member can be suppressed during molding using the resin.

In another aspect, the piezoelectric vibration device of the present invention preferably has the following configuration. The oscillator and the integrated circuit element are arranged on the same mounting surface of the substrate.

In the configuration described above, the oscillator and the integrated circuit element are arranged on the same mounting surface of the substrate, and therefore, a height thereof can be reduced, as compared to a configuration in which the oscillator is arranged on one of principal surfaces of the substrate and the integrated circuit element is arranged on the other one of the principal surfaces.

In another aspect, the piezoelectric vibration device of the present invention preferably has the following configuration. The protecting member is configured such that at least a portion thereof overlaps the frame portion when viewed in a perpendicular direction to the principal surfaces.

In the configuration described above, the protecting member covers a portion of the sealing member in a state of being supported by the frame portion. That is, the molding pressure of the resin applied to the protecting member is received by the frame portion. Thus, deflection of the sealing member can be suppressed during molding using the resin.

In another aspect, the piezoelectric vibration device of the present invention preferably has the following configuration. The oscillator is configured such that a peripheral edge of the sealing member is located more inside than an outer peripheral edge of the frame portion and a peripheral edge of the protecting member is located more outside than the peripheral edge of the sealing member.

In the configuration described above, an end surface of the sealing member is located in a gap between the frame portion and the protecting member. Thus, the resin enters the gap due to a pressure during molding. Therefore, deformation of the end surface of the sealing member located in the gap between the frame portion and the protecting member is suppressed by the resin. The protecting member is larger than the sealing member, so that, even when a position of the protecting member relative to the sealing member is slightly dislocated, the protecting member can cover at least a portion of the sealing member. Thus, deflection of the sealing member can be more reliably suppressed during molding using the resin.

In another aspect, the piezoelectric vibration device of the present invention preferably has the following configuration. The protecting member is thicker than the sealing member.

In the configuration described above, a cross-sectional secondary moment of the protecting member in a perpendicular direction to the principal surfaces of the oscillator is larger than a cross-sectional secondary moment of the sealing member in the perpendicular direction to the principal surfaces. Therefore, the protecting member has a higher rigidity than that of the sealing member even when the protecting member is formed of a same material as the sealing member. Thus, deflection of the sealing member can be suppressed during molding using the resin.

In another aspect, the piezoelectric vibration device of the present invention preferably has the following configuration. The substrate is formed of a resin material. In the configuration described above, the substrate of the piezoelectric vibration device is formed of a resin material that can be easily processed, for example, by cutting. Thus, the piezoelectric vibration device having an arbitrary shape can be easily formed.

In another aspect, the piezoelectric vibration device of the present invention preferably has the following configuration. The protecting member is formed of a brittle material. In the configuration described above, in the protecting member, an amount of deflection relative to a load is smaller as compared to an elastic material. Thus, deflection of the sealing member can be suppressed during molding using the resin.

In another aspect, the piezoelectric vibration device of the present invention preferably has the following configuration. The protecting member is joined to the sealing member via a joining material. In the configuration described above, the protecting member is closely attached to the sealing member via the joining material. With the protecting member closely attached to the sealing member, the resistance of the sealing member to the molding pressure from the resin that is filled in the mold is increased. Thus, deflection of the sealing member can be suppressed during molding using the resin.

In another aspect, the piezoelectric vibration device of the present invention preferably has the following configuration. The electronic component element is at least an integrated circuit element including an oscillation circuit element of the oscillator. In the configuration described above, in the piezoelectric vibration device, the oscillator and the integrated circuit element provided for the oscillator are arranged on a same substrate. Thus, the piezoelectric vibration device can be formed compact.

In another aspect, the piezoelectric vibration device of the present invention preferably has the following configuration. The protecting member is configured of an electronic component element. In the configuration described above, the sealing member is protected by an electronic component element necessary for the piezoelectric vibration device. That is, the protecting member has a necessary function for not only protecting the sealing member but also controlling the piezoelectric vibration device. Thus, the piezoelectric vibration device can be formed compact while the oscillator is protected.

### Advantageous Effects of Invention

According to an embodiment of the present invention, deflection of a sealing member can be suppressed during molding using resin.

### BRIEF DESCRIPTION OF DRAWINGS

FIG. 1 is a plan view illustrating an outline of a whole configuration of a piezoelectric vibration device according to a first embodiment of the present invention.

FIG. 2 is a bottom plan view of the piezoelectric vibration device according to the first embodiment of the present invention.

FIG. 3 is an exploded perspective view of an oscillator in the piezoelectric vibration device according to the first embodiment of the present invention.

FIG. 4 is a plan view of the oscillator in the piezoelectric vibration device according to the first embodiment of the present invention.

FIG. 5 is a cross-sectional view in an arrow direction A in FIG. 4.

FIG. 6 is a cross-sectional view in the arrow direction A in FIG. 4 in a state where the piezoelectric vibration device according to the first embodiment of the present invention is molded using resin in a mold.

FIG. 7 is a cross-sectional view in the arrow direction A in FIG. 4 in a variation of the piezoelectric vibration device according to the first embodiment of the present invention.

FIG. 8 is a plan view illustrating an outline of a whole configuration of a piezoelectric vibration device according to a second embodiment of the present invention.

FIG. 9 is a side view of an oscillator according to the second embodiment of the present invention.

FIG. 10 is a cross-sectional view in an arrow direction D in FIG. 9.

FIG. 11 is a bottom plan view of the oscillator according to the second embodiment of the present invention.

FIG. 12 is a plan view illustrating a size of an integrated circuit element relative to the oscillator according to the second embodiment of the present invention.

FIG. 13 is a side view of the piezoelectric vibration device according to the second embodiment of the present invention.

FIG. 14 is a side view of a variation of the piezoelectric vibration device according to the second embodiment of the present invention.

FIG. 15 is a plan view illustrating an outline of a whole configuration of a piezoelectric vibration device according to a third embodiment of the present invention.

FIG. 16 is a side view illustrating the outline of the whole configuration of the piezoelectric vibration device according to the third embodiment of the present invention.

### DESCRIPTION OF EMBODIMENTS

Embodiments will be described hereinafter with reference to the drawings. In the drawings, the same parts are denoted by the same reference numerals, and description thereof will not be repeated. The dimensions of components in the drawings do not strictly represent actual dimensions of the components and dimensional proportions of the components. In the embodiments below, the term “principal surface” refers to a surface having a largest area in a target member or a surface having a largest area when viewed in a thickness direction in a plate member.

In description of a piezoelectric vibration device 1 that is an embodiment of the present invention that will be described below, a longitudinal direction of an oscillator 2 is an “X-direction,” a lateral direction thereof is a “Y-direction, and a direction that is an opening direction of a frame portion 4 in the oscillator 2 and is orthogonal to the X-direction and the Y-direction is a “Z-direction.” In this embodiment, the X-direction and the Y-direction are directions in a horizontal plane. The Z-direction is the vertical direction. However, these definitions of the directions are not intended to limit orientations of the piezoelectric vibration device 1 when the piezoelectric vibration device 1 is used.

In the description below, the expression “fixed,” “connected,” “joined,” “attached,” or the like (which will be hereinafter collectively referred to as “fixed or the like”) encompasses not only a case where members are directly fixed or the like to each other, but also a case where members are fixed or the like to each other via some other member. That is, in the description below, the expression “fixed or the like” encompasses a meaning that members are directly and indirectly fixed or the like to each other.

### First Embodiment

### <Configuration of Piezoelectric Vibration Device 1>

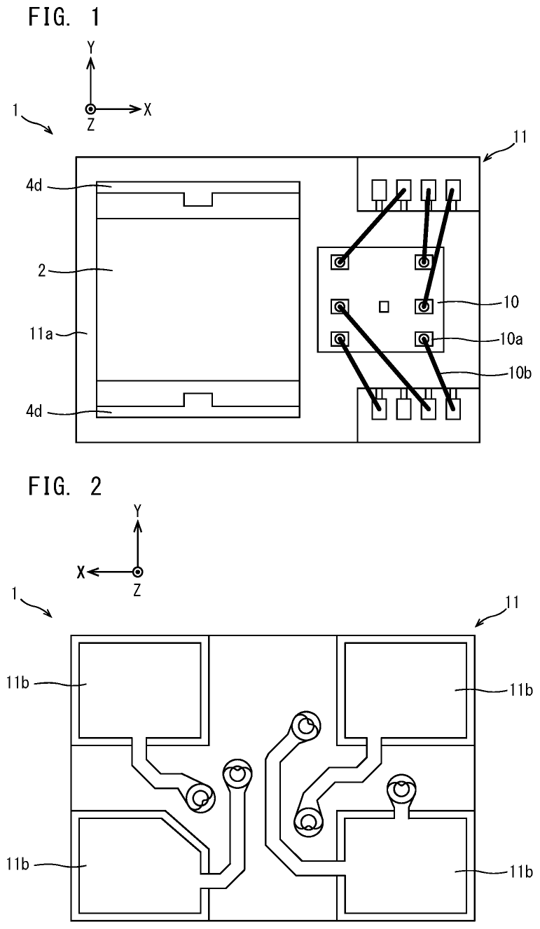

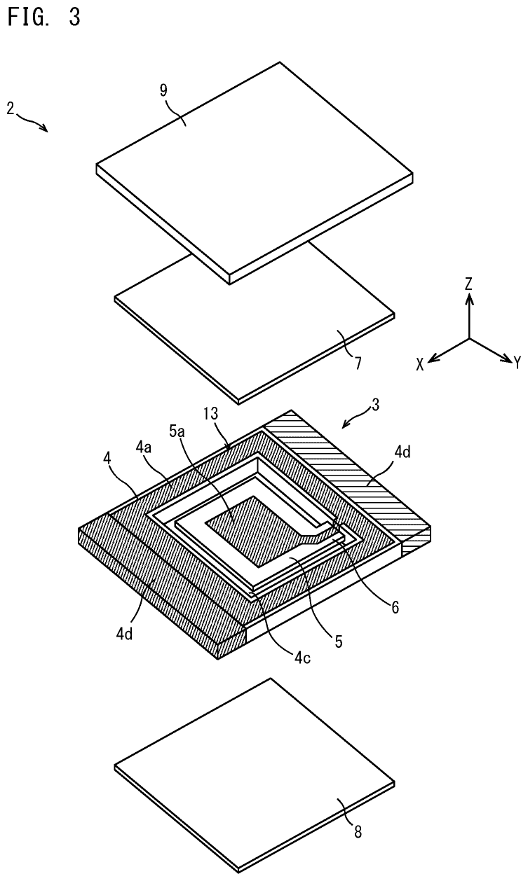

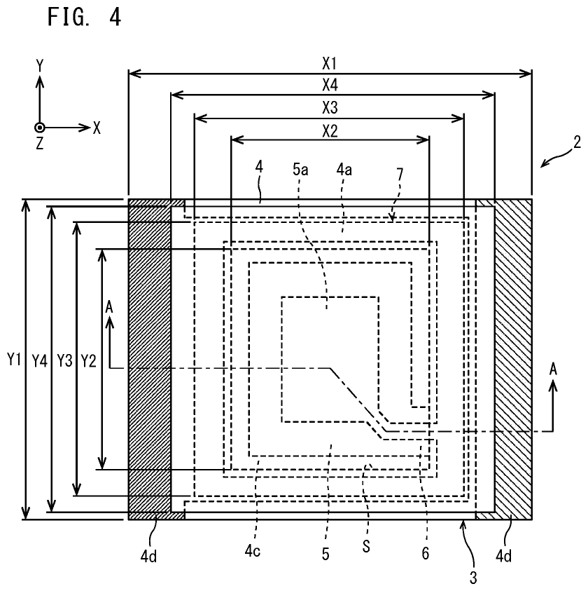

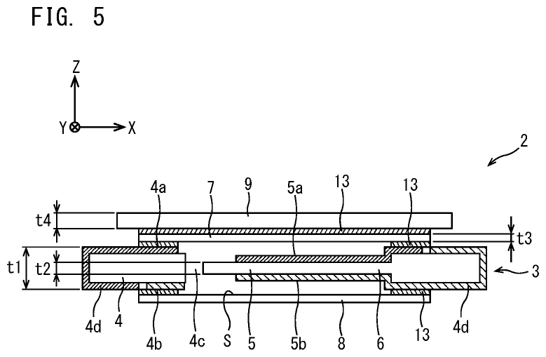

With reference to FIG. 1 to FIG. 5, a piezoelectric vibration device 1 that is a first embodiment of the present invention will be described. FIG. 1 is a plan view illustrating an outline of a whole configuration of the piezoelectric vibration device 1. FIG. 2 is a bottom plan view illustrating the outline of the whole configuration of the piezoelectric vibration device 1. FIG. 3 is an exploded perspective view illustrating an outline of a whole configuration of an oscillator 2 in the piezoelectric vibration device 1. FIG. 4 is a plan view of the oscillator 2. FIG. 5 is a cross-sectional view in an arrow direction A in FIG. 4.

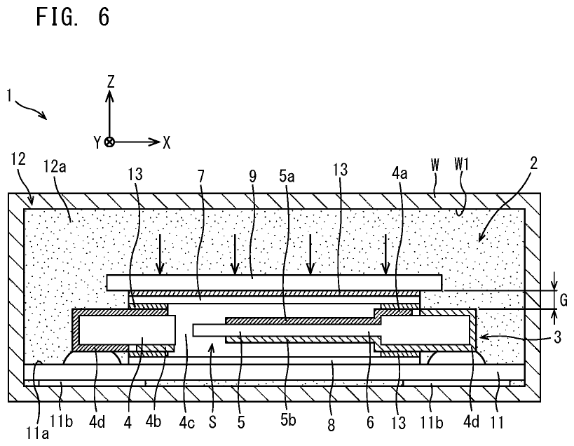

As illustrated in FIG. 1, the piezoelectric vibration device 1 includes the oscillator 2, an integrated circuit element 10, a substrate 11, and a molding portion 12 (see FIG. 6).

As illustrated in FIG. 3 to FIG. 5, the oscillator 2 is a piezoelectric element with a piezoelectric body that converts an applied force to a voltage or converts an applied voltage to a force. The oscillator 2 includes a piezoelectric vibration plate 3, a first sealing member 7, a second sealing member 8, and a protecting member 9.

The piezoelectric vibration plate 3 is a rectangular crystal vibrating piece that is crystal cut out in a specific direction. The piezoelectric vibration plate 3 includes a frame portion 4, a vibrating portion 5, and a connecting portion 6. In the piezoelectric vibration plate 3, the frame portion 4, the vibrating portion 5, and the connecting portion 6 are molded into one body. That is, the frame portion 4, the vibrating portion 5, and the connecting portion 6 are formed as a single member.

As illustrated in FIG. 4 and FIG. 5, the frame portion 4 surrounds the vibrating portion 5. The frame portion 4 is formed of a plate material having a rectangular shape in a plan view that is a view in a perpendicular direction to a pair of principal surfaces thereof each having a largest area. The frame portion 4 is a frame member that includes the pair of principal surfaces each having a rectangular opening when viewed in the Z-direction, that is, in a plan view. That is, the frame portion 4 includes a rectangular through section 4c that penetrates from one of the principal surfaces to the other one of the principal surfaces.

A space between the pair of principal surfaces of the frame portion 4, that is, a thickness of the frame portion 4, is a thickness t1. One of the principal surfaces of the frame portion 4 includes a first joined surface 4a joined to the first sealing member 7. The other one of the principal surfaces of the frame portion 4 includes a second joined surface 4b joined to the second sealing member 8. Each of both end portions of the frame portion 4 in the longitudinal direction includes an oscillator mounting terminal 4d.

The vibrating portion 5 is a piezoelectric body. The vibrating portion 5 is a plate material having an approximately rectangular shape in a plan view that is a view in a perpendicular direction to a pair of principal surfaces thereof each having a largest area. The vibrating portion 5 is arranged inside a frame of the frame portion 4. The vibrating portion 5 is arranged such that the pair of principal surfaces are opposed to the openings of the frame portion 4 when viewed in the Z-direction, that is, in a plan view. The principal surfaces of the vibrating portion 5 are arranged approximately in parallel to the principal surfaces of the frame portion 4. A space between the pair of principal surfaces of the vibrating portion 5, that is, a thickness of the vibrating portion 5, is a thickness t2 that is smaller than the thickness t1 of the frame portion 4. The vibrating portion 5 is arranged between the pair of principal surfaces of the frame portion 4 inside the frame of the frame portion 4.

A portion of the vibrating portion 5 is connected to the frame portion 4 via the connecting portion 6 having a plate shape. The vibrating portion 5 is held in a cantilever-supported state on the frame portion 4 via the connecting portion 6. That is, the vibrating portion 5 is surrounded by the frame portion 4 with the through section 4c interposed therebetween. One of the principal surfaces of the vibrating portion 5 includes a first excitation electrode 5a. The other one of the principal surfaces of the vibrating portion 5 includes a second excitation electrode 5b. The first excitation electrode 5a is connected to one of the oscillator mounting terminals 4d. The second excitation electrode 5b is connected to the other one of the oscillator mounting terminals 4d.

The first sealing member 7 and the second sealing member 8 that are sealing members seal the frame of the frame portion 4. Each of the first sealing member 7 and the second sealing member 8 is a resin film having a rectangular shape in a plan view that is a view in a perpendicular direction to a pair of principal surfaces thereof each having a largest area. Each of the first sealing member 7 and the second sealing member 8 is a polyimide resin film having heat resistance of, for example, approximately 300° C. Each of the first sealing member 7 and the second sealing member 8 has a thickness t3 of about 20 μm to 50 μm.

A width X3 of each of the first sealing member 7 and the second sealing member 8 in the X-direction that is the longitudinal direction is smaller than a width X1 of an outer edge of the frame portion 4 in the X-direction, and is larger than a width X2 of the opening that is an inner edge of the frame portion 4 in the X-direction, when viewed in the Z-direction, that is, in a plan view. When viewed in the Z-direction, a width Y3 of each of the first sealing member 7 and the second sealing member 8 in the lateral direction that is a perpendicular direction to the X-direction is smaller than a width Y1 of the outer edge of the frame portion 4 in the Y-direction, and is larger than a width Y2 of the opening that is the inner edge of the frame portion 4 in the Y-direction. That is, each of the first sealing member 7 and the second sealing member 8 is smaller than the frame portion 4 and is larger than the opening of the frame portion 4.

The first sealing member 7 is joined to the first joined surface 4a of one of the principal surfaces of the frame portion 4 by a joining material 13 that is a thermoplastic adhesive. A peripheral edge of the first sealing member 7 is located more inside than the outer edge of the frame portion 4 and more outside than the inner edge of the frame portion 4. End portions of the first sealing member 7 in the X-direction are joined to the first joined surface 4a of the one of the principal surfaces of the frame portion 4 located in the X-direction. End portions of the first sealing member 7 in the Y-direction are joined to the first joined surface 4a of the one of the principal surfaces of the frame portion 4 located in the Y-direction. That is, when viewed in the Z-direction, a portion of the first sealing member 7 overlapping the first joined surface 4a is joined to the frame portion 4 by the joining material 13. The first sealing member 7 covers the opening of the one of the principal surfaces of the frame portion 4. Thus, the first sealing member 7 closes the opening of the one of the principal surfaces of the frame portion 4.

The second sealing member 8 is joined to the second joined surface 4b of the other one of the principal surfaces of the frame portion 4 by the joining material 13. A peripheral edge of the second sealing member 8 is located more inside than the outer edge of the frame portion 4 and more outside than the inner edge of the frame portion 4. End portions of the second sealing member 8 in the X-direction are joined to the second joined surface 4b of the other one of the principal surfaces of the frame portion 4 located in the X-direction. End portions of the second sealing member 8 in the Y-direction are joined to the second joined surface 4b of the other one of the principal surfaces of the frame portion 4 located in the Y-direction. That is, when viewed in the Z-direction, a portion of the second sealing member 8 overlapping the second joined surface 4b is joined to the frame portion 4 by the joining material 13. The second sealing member 8 covers the opening of the one of the principal surfaces of the frame portion 4. Thus, the second sealing member 8 closes the opening of the other one of the principal surfaces of the frame portion 4.

The protecting member 9 suppresses deflection of at least the first sealing member 7 of the first sealing member 7 and the second sealing member 8 caused by a molding pressure of resin forming the molding portion 12. The protecting member 9 is a plate member having a rectangular shape in a plan view that is a view in a perpendicular direction to a pair of principal surfaces thereof each having a largest area. The protecting member 9 is formed of silicon that is a brittle material. It is desirable that the protecting member 9 has a rigidity that allows a maximum amount of deflection to be 20 μm or less in a state of being held at both ends in the longitudinal direction under application of a pressure generated during molding using resin.

Therefore, for the protecting member 9, a modulus of longitudinal elasticity of a material and a cross-sectional secondary moment in the Z-direction that is a direction of a plan view are set such that the protecting member 9 has a higher rigidity than that of at least the first sealing member 7 of the first sealing member 7 and the second sealing member 8. In this embodiment, the protecting member 9 is silicon. In this embodiment, it is desirable that the protecting member 9 has a thickness t4 of about 30 μm to 100 μm. The thickness t4 of the protecting member 9 is larger than the thickness t3 of each of the first sealing member 7 and the second sealing member 8.

A width X4 of the protecting member 9 in the X-direction that is the longitudinal direction is smaller than the width X1 of the outer edge of the frame portion 4 of the piezoelectric vibration plate 3 in the X-direction and is larger than the width X3 of the first sealing member 7 in the X-direction, when viewed in the Z-direction. The width Y4 of the protecting member 9 in the Y-direction that is a perpendicular direction to the X-direction is smaller than the width Y1 of the outer edge of the frame portion 4 in the Y-direction and is larger than the width Y3 of the first sealing member 7 in the Y-direction, when viewed in the Z-direction. That is, the protecting member 9 is smaller than the frame portion 4 and is larger than the first sealing member 7.

The protecting member 9 is joined to a surface of the first sealing member 7 extending perpendicular to the Z-direction by a thermoplastic additive or a die attach agent, that is, the joining material 13. A peripheral edge of the protecting member 9 is located between the peripheral edge of the first sealing member 7 and the outer edge of the frame portion 4. That is, a peripheral edge portion of the protecting member 9 overlaps the first joined surface 4a of the frame portion 4, when viewed in the Z-direction. Thus, the protecting member 9 is supported by the frame portion 4 at the peripheral edge portion thereof. The protecting member 9 covers the opening of the one of the principal surfaces of the frame portion 4 via the first sealing member 7. That is, the protecting member 9 covers the entire first sealing member 7 including a portion overlapping the opening when viewed in the Z-direction.

The oscillator 2 configured in the above-described manner has a three-layer structure including the piezoelectric vibration plate 3, the first sealing member 7 that closes the opening of the one of the principal surfaces of the piezoelectric vibration plate 3, and the second sealing member 8 that closes the opening of the other one of the principal surfaces of the piezoelectric vibration plate 3. The oscillator 2 has an internal space S formed by the frame portion 4 of the piezoelectric vibration plate 3, the first sealing member 7, and the second sealing member 8. The oscillator 2 includes the vibrating portion 5 arranged in the internal space S. An inert gas, such as nitrogen gas, is enclosed in the internal space S. The oscillator 2 oscillates at a predetermined frequency by a voltage applied from each of the oscillator mounting terminals 4d.

As illustrated in FIG. 1, the integrated circuit element 10 that is an electronic component element is an IC that controls the oscillator 2. The integrated circuit element 10 includes an electronic circuit, such as an oscillation circuit that is connected to a thermosensitive element (thermistor) that detects a surrounding temperature state and generates a predetermined oscillation output, or the like. The integrated circuit element 10 outputs the oscillation output generated by the oscillation circuit as a reference signal, such as a clock signal, to outside via integrated circuit element mounting terminals 10a. A portion of the integrated circuit element 10 except the integrated circuit element mounting terminals 10a is covered by resin.

As illustrated in FIG. 1 and FIG. 2, the substrate 11 is an insulating substrate that electrically connects the oscillator 2 and the integrated circuit element 10 to each other with a wiring pattern (not illustrated) and forms the oscillator 2 and the integrated circuit element 10 as an integrated body. The substrate 11 is formed of a resin material. The substrate 11 includes, as a base material, for example, glass epoxy resin that is an insulator. One of principal surfaces of the substrate 11 is formed as a mounting surface 11a including a circuit formed of a conductor, such as copper. The other one of the principal surfaces of the substrate 11 includes a substrate mounting terminal 11b used for mounting the substrate 11 on an external substrate. The circuit of the mounting surface 11a is electrically connected to the substrate mounting terminal 11b. In this embodiment, the substrate 11 has a thickness of, for example, 0.17 mm.

The oscillator 2 and the integrated circuit element 10 are each mounted on the mounting surface 11a of the substrate 11. Each of both the oscillator mounting terminals 4d of the oscillator 2 is electrically connected to the circuit of the mounting surface 11a by the conductive joining material 13. At this time, the oscillator 2 is arranged such that the principal surfaces thereof covered by the first sealing member 7 and the second sealing member 8 face in the Z-direction. The oscillator 2 is arranged such that the second sealing member 8 is opposed to the mounting surface 11a. The second sealing member 8 contacts the mounting surface 11a. Similarly, each integrated circuit element mounting terminal 10a of the integrated circuit element 10 is electrically connected to the circuit of the mounting surface 11a of the substrate 11 by a wire 10b. In a manner described above, the oscillator 2 and the integrated circuit element 10 are arranged side by side on the mounting surface 11a of the substrate 11.

The oscillator 2 mounted on the substrate 11 is electrically connected to the external substrate from the oscillator mounting terminal 4d via an unillustrated wiring pattern of the substrate 11 and the substrate mounting terminal 11b. The vibrating portion 5 of the oscillator 2 is held in a cantilever-supported state on the frame portion 4 of the piezoelectric vibration plate 3 by the connecting portion 6. Thus, the vibrating portion 5 oscillates at a predetermined frequency by a voltage applied from the external substrate.

The molding portion 12 protects the substrate 11 and at least the oscillator 2 of the oscillator 2 and the integrated circuit element 10 mounted on the substrate 11 (see FIG. 6). The molding portion 12 is thermosetting resin, such as epoxy resin 12a. The molding portion 12 covers the substrate 11 and at least the oscillator 2 of the oscillator 2 and the integrated circuit element 10 mounted on the substrate 11 with the epoxy resin 12a cured by heat. In this embodiment, the molding portion 12 covers the substrate 11, and the oscillator 2 and the integrated circuit element 10 mounted on the substrate 11.

Next, with reference to FIG. 6, a state of the first sealing member 7 when the oscillator 2 and the substrate 11 are covered by the molding portion 12 will be described. The oscillator 2 and the substrate 11 are arranged in a cavity of a mold W. FIG. 6 is a cross-sectional view in the arrow direction A in FIG. 4 in a state where the piezoelectric vibration device 1 is molded using resin in the mold W.

As illustrated in FIG. 6, the molding portion 12 is molded by a transfer system in which melted resin is filled in the cavity of the mold W. The melted epoxy resin 12a is filled in the cavity by an unillustrated plunger. The epoxy resin 12a is filled in the cavity by the plunger with a predetermined filling pressure. When an entire portion of the cavity is filled with the epoxy resin 12a, the epoxy resin 12a is pressed by a predetermined molding pressure for a predetermined time. The epoxy resin 12a is cured by heat while being held with the predetermined molding pressure. The epoxy resin 12a cured by heat serves as the molding portion 12 and covers the oscillator 2 and the substrate 11.

With regard to the oscillator 2 and the substrate 11 arranged in the cavity that is filled with the epoxy resin 12a, the epoxy resin 12a contacts the frame portion 4 on the piezoelectric vibration plate 3, the protecting member 9, and the substrate 11. On the other hand, one principal surface of the first sealing member 7 is covered by a corresponding one of the principal surfaces of the protecting member 9 when viewed in the Z-direction. The first sealing member 7 and the protecting member 9 are joined to each other by the joining material 13. The protecting member 9 is closely attached to the first sealing member 7. Thus, the epoxy resin 12a does not contact the principal surfaces of the first sealing member 7. The second sealing member 8 is covered by the substrate 11 when viewed in the Z-direction. Thus, the epoxy resin 12a does not contact the principal surfaces of the second sealing member 8. The connecting portion 6 and the vibrating portion 5 of the piezoelectric vibration plate 3 are sealed in the internal space S with the first sealing member 7 and the second sealing member 8, and thus, do not contact the epoxy resin 12a.

While the epoxy resin 12a is held by a molding pressure, the molding pressure is applied to the frame portion 4 of the piezoelectric vibration plate 3, the protecting member 9, and the substrate 11 that the epoxy resin 12a contacts in the oscillator 2 and on the substrate 11 from a perpendicular direction to a contact surface with the epoxy resin 12a. A holding pressure is applied in the Z-direction, to the principal surface of the protecting member 9 that extends in a perpendicular direction to the Z-direction (see arrows). The cross-sectional secondary moment of the protecting member 9 in the Z-direction that is a perpendicular direction to a principal surface of the oscillator 2 is larger than the cross-sectional secondary moment of the first sealing member 7 in the Z-direction. The protecting member 9 is formed of a brittle material having a larger modulus of longitudinal elasticity than that of a resin material. Therefore, the rigidity of the protecting member 9 is increased to a higher level than that of the first sealing member 7 by a shape and a material.

The protecting member 9 is deflected toward the piezoelectric vibration plate 3 by about 20 μm in the Z-direction by the predetermined molding pressure. At this time, the first sealing member 7 joined with the protecting member 9 is deflected toward the piezoelectric vibration plate 3 by about 20 μm in the Z-direction along deflection of the protecting member 9 in the Z-direction. The first sealing member 7 before being deflected is distant from the vibrating portion 5 of the piezoelectric vibration plate 3 by a larger distance than 20 μm in the Z-direction. Thus, the first sealing member 7 does not contact the vibrating portion 5 even when the first sealing member 7 is deflected toward the piezoelectric vibration plate 3 in the Z-direction by the molding pressure.

The peripheral edge of the protecting member 9 is located more outside than the peripheral edge of the first sealing member 7 and more inside than an outer peripheral edge of the frame portion 4. That is, a gap G equal to a thickness obtained by adding the thickness t3 of the first sealing member 7 and the thickness of the joining material 13 is generated between the peripheral edge portion of the protecting member 9 located more outside than the first sealing member 7 and a joined surface of the frame portion 4. The epoxy resin 12a enters in the gap G. Thus, the epoxy resin 12a contacts end surfaces of the first sealing member 7 that extend in a perpendicular direction to the X-direction and end surfaces thereof that extend in a perpendicular direction to the Y-direction. Movements of the first sealing member 7 in the X-direction and the Y-direction are limited by heat curing of the epoxy resin 12a.

As the oscillator 2 of the piezoelectric vibration device 1 configured as described above, the oscillator 2 having a three-layer structure, in which the piezoelectric vibration plate 3 that supports the vibrating portion 5 having a smaller thickness than that of the frame portion 4 inside the frame of the frame portion 4 is covered by the first sealing member 7 and the second sealing member 8 that are resin films, is provided. The first sealing member 7 that closes the principal surface of the frame portion 4 having the opening is covered by the protecting member 9. Thus, the epoxy resin 12a forming the molding portion 12 does not contact the principal surface of the first sealing member 7 that is perpendicular to the Z-direction. The protecting member 9 covers the first sealing member 7 with the peripheral edge thereof supported by the frame portion 4. That is, the molding pressure of the epoxy resin 12a applied to the protecting member 9 is received by the frame portion 4.

The oscillator 2 is configured such that the molding pressure applied to the first sealing member 7 is reduced in accordance with a ratio of an area of the protecting member 9 to an area of a portion of the first sealing member 7 that covers the opening of the frame portion 4. In this embodiment, the portion of the first sealing member 7 that covers the opening of the frame portion 4 is entirely covered by the protecting member 9. Accordingly, in the oscillator 2, all the molding pressure of the epoxy resin 12a applied to the first sealing member 7 is received by the protecting member 9. Thus, deflection of at least the first sealing member 7 of the first sealing member 7 and the second sealing member 8 can be suppressed during molding using the epoxy resin 12a.

In a state where the oscillator 2 and the integrated circuit element 10 are joined to the substrate 11, an upper surface of the oscillator 2 is located higher than an upper surface of the integrated circuit element 10. Therefore, a thickness of the piezoelectric vibration device 1 is a total of a thickness of the oscillator 2 and a thickness obtained by the substrate 11 and molding resin (the epoxy resin 12a). At this time, resistance of the first sealing member 7 to the molding pressure from the molding resin is increased because the first sealing member 7 is covered by the protecting member 9. Accordingly, the piezoelectric vibration device 1 can suppress deflection of the first sealing member 7 during molding using the epoxy resin 12a. Thus, the piezoelectric vibration device 1 is configured to have a three-layer structure in which the frame portion 4 including the vibrating portion 5 inside the frame thereof is covered by the first sealing member 7 and the second sealing member 8 that are resin films, so that the thickness of the piezoelectric vibration device 1 can be reduced.

The oscillator 2 of the piezoelectric vibration device 1 has the gap G between the frame portion 4 and the protecting member 9 because the first sealing member 7 is provided. The epoxy resin 12a enters the gap G due to the molding pressure. Accordingly, deformation of the first sealing member 7 arranged between the frame portion 4 and the protecting member 9 can be suppressed by the epoxy resin 12a cured by heat. The protecting member 9 is larger than the first sealing member 7, and therefore, can cover at least a portion of the first sealing member 7 even when a position of the protecting member 9 relative to the first sealing member 7 is slightly dislocated in the X-direction and the Y-direction. Thus, deflection of at least the first sealing member 7 of the first sealing member 7 and the second sealing member 8 can be suppressed during molding using the epoxy resin 12a.

The substrate 11 of the piezoelectric vibration device 1 is formed of a glass epoxy resin material that can be easily processed, for example, by cutting. Thus, the piezoelectric vibration device 1 having an arbitrary shape can be easily formed.

### Variation of First Embodiment

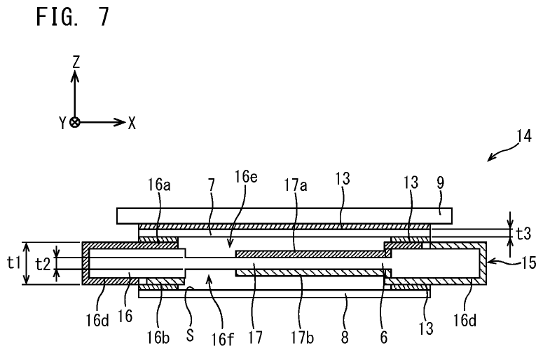

In the first embodiment described above, the oscillator 2 includes the through section 4c between the frame portion 4 and the vibrating portion 5 and supports the vibrating portion 5 in a cantilever state. However, as illustrated in FIG. 7, the oscillator 2 may have a configuration in which the through section 4c is not provided between the frame portion 4 and the vibrating portion 5. FIG. 7 is a cross-sectional view in an arrow direction A in FIG. 4 in a variation of the piezoelectric vibration device.

As illustrated in FIG. 7, an oscillator 14 that does not include the through section 4c includes a piezoelectric vibration plate 15, a first sealing member 7, a second sealing member 8, and a protecting member 9. In the piezoelectric vibration plate 15, a frame portion 16 and a vibrating portion 17 are integrally molded. That is, the frame portion 16 and the vibrating portion 17 are configured as a single member. Note that, in the following embodiment, specific description of similar points to those in the embodiment already described will be omitted and only a portion which differs from the already described embodiment will be described in detail.

The frame portion 16 surrounds the vibrating portion 17. The frame portion 16 is formed of a plate material having a rectangular shape in a plan view that is a view in a perpendicular direction to a pair of principal surfaces thereof each having a largest area. The frame portion 16 is a frame member having the pair of principal surfaces each having a rectangular opening when viewed in the Z-direction that is a plan view. The frame portion 16 includes a first joined surface 16a joined to the first sealing member 7 and a second joined surface 16b joined to the second sealing member 8. Each of both end portions of the frame portion 16 in the longitudinal direction has an oscillator mounting terminal 16d. The frame portion 16 includes a recessed portion 16e having a rectangular shape in one of the principal surfaces thereof and a recessed portion 16f having a rectangular shape in the other one of the principal surfaces thereof when viewed in the Z-direction. The recessed portion 16e in the one of the principal surfaces and the recessed portion 16f in the other one of the principal surfaces do not communicate with each other. That is, the frame portion 16 does not have a through portion.

The vibrating portion 17 is a piezoelectric body. The vibrating portion 17 is a plate material having an approximately rectangular shape in a plan view that is a view in the perpendicular direction to a pair of principal surfaces thereof each having a largest area. One of the principal surfaces of the vibrating portion 17 is a bottom surface of one recessed portion 16e in the frame portion 16. The other one of the principal surfaces of the vibrating portion 17 is a bottom surface of the other recessed portion 16f in the frame portion 16. The vibrating portion 17 is arranged such that the pair of principal surfaces thereof are opposed to the openings of the frame portion 16 when viewed in the Z-direction, that is, in a plan view. The principal surfaces of the vibrating portion 17 are arranged approximately in parallel to the principal surfaces of the frame portion 16. The vibrating portion 17 is arranged between the pair of the principal surfaces of the frame portion 16 inside a frame of the frame portion 16. The vibrating portion 17 has a peripheral edge connected to the frame portion 16. That is, the vibrating portion 17 is supported by the frame portion 16 at the entire peripheral edge. The one of the principal surfaces of the vibrating portion 17 includes a first excitation electrode 17a. The other one of the principal surfaces of the vibrating portion 17 includes a second excitation electrode 17b.

As described above, the oscillator 14 of the piezoelectric vibration device 1 includes the recessed portion 16e in the one of the principal surfaces of the frame portion 16 and the recessed portion 16f in the other one of the principal surfaces thereof. The bottom surfaces of the recessed portion 16e and the recessed portion 16f form the vibrating portion 17. The oscillator 14 has a three-layer structure in which the opening of the recessed portion 16e of the frame portion 16 is covered by the first sealing member 7 and the opening of the recessed portion 16f is covered by the second sealing member 8. The first sealing member 7 is covered by the protecting member 9, and therefore, resistance to the molding pressure from the epoxy resin 12a is increased. Accordingly, the first sealing member 7 can suppress deflection of the first sealing member 7 during molding using the epoxy resin 12a.

### Second Embodiment

### <Configuration of Piezoelectric Vibration Device 21>

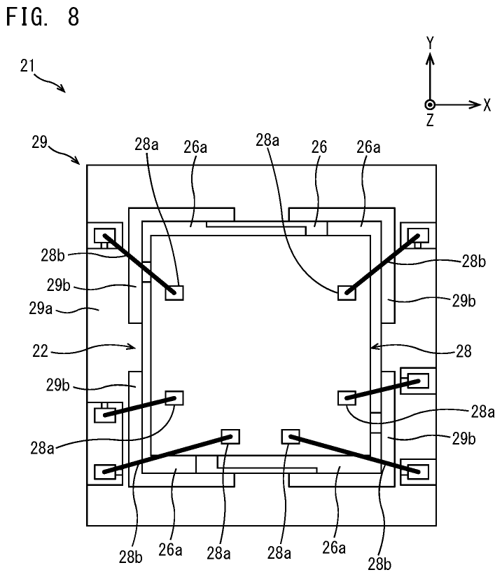

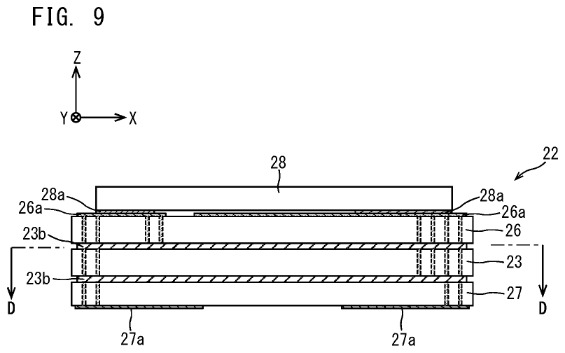

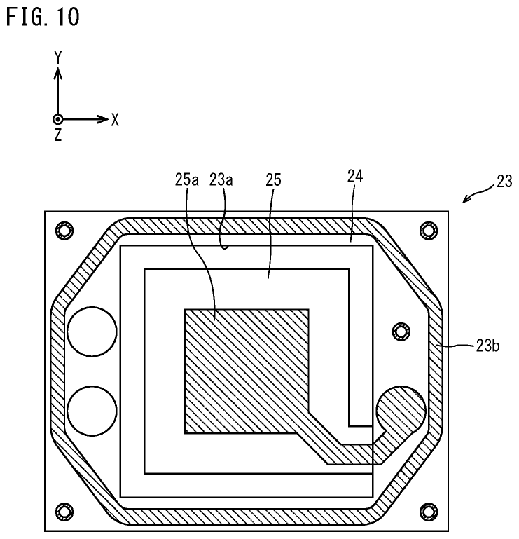

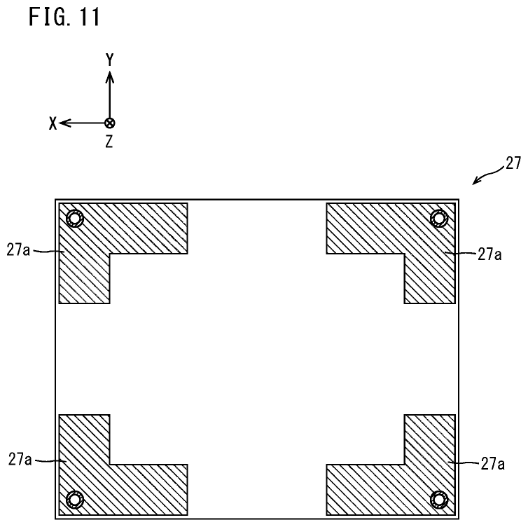

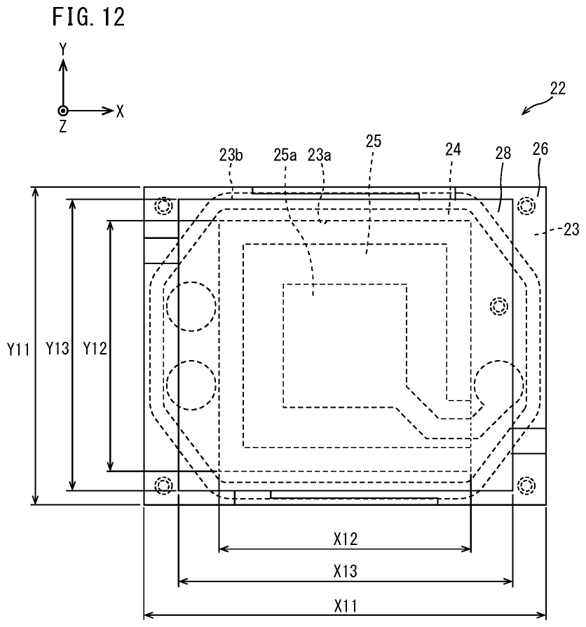

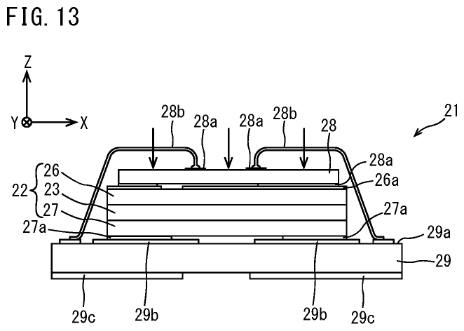

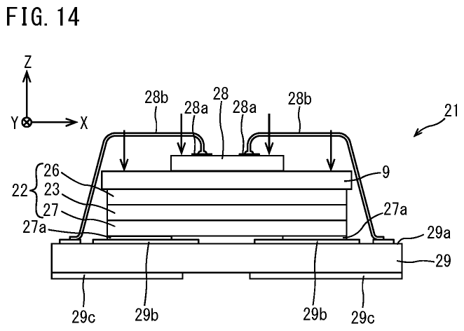

Next, with reference to FIG. 8 to FIG. 13, a piezoelectric vibration device 21 that is a second embodiment of the present invention will be described. FIG. 8 is a plan view illustrating an outline of a whole configuration of the piezoelectric vibration device 21 according to the second embodiment of the present invention. FIG. 9 is a side view of an oscillator 22 in the piezoelectric vibration device 21. FIG. 10 is a cross-sectional view in an arrow direction D in FIG. 9. FIG. 11 is a bottom plan view of the oscillator 22. FIG. 12 is a plan view illustrating a size of an integrated circuit element 28 relative to the oscillator 22. FIG. 13 is a side view of the piezoelectric vibration device 21. FIG. 14 is a side view of a variation of the piezoelectric vibration device 21. Note that, in the following embodiment, specific description of similar points to those in the embodiment already described will be omitted and only a portion which differs from the already described embodiment will be described in detail.

As illustrated in FIG. 8, the piezoelectric vibration device 21 includes the oscillator 22, the integrated circuit element 28, a substrate 29, and a molding portion (not illustrated).

As illustrated in FIG. 9 to FIG. 11, the oscillator 22 is a piezoelectric oscillator including a piezoelectric vibration plate 23, a first sealing member 26, and a second sealing member 27. The oscillator 22 is a three-layer stacked body having a sandwich structure in which the piezoelectric vibration plate 23 is sandwiched between the first sealing member 26 and the second sealing member 27.

As illustrated in FIG. 10, the piezoelectric vibration plate 23 is a rectangular plate member formed of crystal that is a piezoelectric material. The piezoelectric vibration plate 23 includes a frame portion 24 and a vibrating portion 25. In the piezoelectric vibration plate 23, the frame portion 24 and the vibrating portion 25 are integrally molded. That is, the frame portion 24 and the vibrating portion 25 are configured as a single member.

The frame portion 24 surrounds the vibrating portion 25. The frame portion 24 is formed in outer edge portions of a pair of principal surfaces of the piezoelectric vibration plate 23 each having a largest area. A portion surrounded by the frame portion 24 is recessed to a lower level than the principal surfaces of the piezoelectric vibration plate 23. That is, the frame portion 24 is a frame shaped portion having openings each having a rectangular shape when viewed in the Z-direction that is a perpendicular direction to the principal surfaces.

A pair of excitation electrodes 25a are arranged in respective portions of one and the other one of the principal surfaces of the piezoelectric vibration plate 23 surrounded by the frame portion 24. The pair of the excitation electrodes 25a are arranged to be opposed to each other in a thickness direction of the piezoelectric vibration plate 23. The piezoelectric vibration plate 23 includes a through portion 23a that penetrates from one of the principal surfaces to the other one of the principal surfaces such that the through portion 23a surrounds the pair of excitation electrodes 25a in the portion surrounded by the frame portion 24 when viewed in the Z-direction that is a perpendicular direction to the pair of principal surfaces of the piezoelectric vibration plate 23 each having a largest area. The through portion 23a passes through the piezoelectric vibration plate 23 to surround the pair of excitation electrodes 25a with portions of the excitation electrodes 25a left non-surrounded. Thus, a portion in which the pair of excitation electrodes 25a are arranged is configured as a plate member having a cantilever structure. That is, the portion in which the pair of excitation electrodes 25a are arranged is configured as the vibrating portion 25 that can vibrate in the Z-direction.

The vibrating portion 25 is a piezoelectric body. The vibrating portion 25 is a plate portion having an approximately rectangular shape in a plan view that is a view in a perpendicular direction to a pair of principal surfaces thereof each having a largest area. The vibrating portion 25 is arranged inside a frame of the frame portion 24. The vibrating portion 25 is arranged such that the pair of principal surfaces thereof are opposed to the opening of the frame portion 24 when viewed in the Z-direction. The principal surfaces of the vibrating portion 25 are arranged approximately in parallel to principal surfaces of the frame portion 24. A thickness of the vibrating portion 25 is smaller than a thickness of the frame portion 24. The vibrating portion 25 is arranged between the pair of principal surfaces of the frame portion 24 inside the frame of the frame portion 24.

One of the principal surfaces of the frame portion 24 includes a joining material 23b that is joined to the first sealing member 26 to surround the vibrating portion 25. Similarly, the other one of the principal surfaces of the frame portion 24 includes a joining material 23b that is joined to the second sealing member 27 to surround the vibrating portion 25. Each of the joining materials 23b is formed into a ring shape. Each of the joining materials 23b is a PVD film formed of the same metal as metal that forms the pair of excitation electrodes 25a.

The first sealing member 26 seals the vibrating portion 25 of the piezoelectric vibration plate 23. The first sealing member 26 is a rectangular plate member formed of the same crystal as the piezoelectric vibration plate 23. The first sealing member 26 has approximately the same shape as the piezoelectric vibration plate 23. That is, the first sealing member 26 has a shape that can entirely cover one of the principal surfaces of the piezoelectric vibration plate 23 when one of the principal surfaces of the first sealing member 26 is arranged to be opposed to the one of the principal surfaces of the piezoelectric vibration plate 23. That is, the first sealing member 26 has a shape that can entirely cover the opening of the frame portion 24. The one of the principal surfaces of the first sealing member 26 includes a joining material that is joined to the joining material 23b of the piezoelectric vibration plate 23. The joining material of the first sealing member 26 is a PVD film formed of the same metal as metal forming the joining material 23b of the piezoelectric vibration plate 23.

As illustrated in FIG. 9, the first sealing member 26 includes external portion mounting terminals 26a electrically connected to integrated circuit element mounting terminals 28a of the integrated circuit element 28 on the other one of the principal surfaces thereof. The external portion mounting terminals 26a each are a plate-shaped terminal formed of conductive metal.

As illustrated in FIG. 11, the second sealing member 27 seals the vibrating portion 25 of the piezoelectric vibration plate 23. The second sealing member 27 is a rectangular plate member formed of the same crystal as the piezoelectric vibration plate 23. The second sealing member 27 has approximately the same shape as the piezoelectric vibration plate 23. That is, the second sealing member 27 has a shape that can entirely cover the other one of the principal surfaces of the piezoelectric vibration plate 23 when one of the principal surfaces of the second sealing member 27 is arranged to be opposed to the other one of the principal surfaces of the piezoelectric vibration plate 23. That is, the second sealing member 27 has a shape that can entirely cover the opening of the frame portion 24. The one of the principal surfaces of the second sealing member 27 includes a joining material that is joined to the joining material 23b of the piezoelectric vibration plate 23. The joining material of the second sealing member 27 is a PVD film formed of the same metal as the metal that forms the joining material 23b of the piezoelectric vibration plate 23.

The second sealing member 27 includes, on the other one of the principal surfaces thereof, four oscillator mounting terminals 27a each being electrically connected to an electrode of the substrate 29. Each of the four oscillator mounting terminals 27a is a plate-shaped terminal formed of conductive metal. Each of the four oscillator mounting terminals 27a is formed into an approximately L-shape when viewed in the Z-direction.

As illustrated in FIG. 9, the first sealing member 26 is arranged on one of the principal surfaces of the piezoelectric vibration plate 23. The one of the principal surfaces of the piezoelectric vibration plate 23 is covered by the first sealing member 26. At this time, the joining material 23b of the one of the principal surfaces of the piezoelectric vibration plate 23 and the joining material of the first sealing member 26 are diffusion-bonded. Thus, the excitation electrode 24a at the one of the principal surfaces of the piezoelectric vibration plate 23 is hermetically sealed with the first sealing member 26.

The second sealing member 27 is arranged on the other one of the principal surfaces of the piezoelectric vibration plate 23. The other one of the principal surfaces of the piezoelectric vibration plate 23 is covered by the second sealing member 27. At this time, the joining material 23b of the other one of the principal surfaces of the piezoelectric vibration plate 23 and the joining material of the second sealing member 27 are diffusion-bonded. Thus, the excitation electrode 24a at the other one of the principal surfaces of the piezoelectric vibration plate 23 is hermetically sealed with the second sealing member 27.

The oscillator 22 configured in a manner described above is configured as a package having a sandwich structure in which each of the principal surfaces of the piezoelectric vibration plate 23 is sealed with a corresponding one of the first sealing member 26 and the second sealing member 27. The oscillator 22 is configured such that both the principal surfaces of the piezoelectric vibration plate 23 are covered by the first sealing member 26 and the second sealing member 27, and thus, an internal space that includes the vibrating portion 25 of the piezoelectric vibration plate 23 is formed. That is, the oscillator 22 is configured such that the vibrating portion 25 including the pair of excitation electrodes 25a is hermetically sealed in the internal space of the package.

As illustrated in FIG. 9, the integrated circuit element 28 is an IC that controls the oscillator 2. A configuration of the integrated circuit element 28 is identical to the configuration of the integrated circuit element 10 of the first embodiment, and therefore, description thereof will be omitted. A portion of the integrated circuit element 28 except the integrated circuit element mounting terminals 28a is covered by resin. The integrated circuit element 28 is mounted on the other one of the principal surfaces of the first sealing member 26. The integrated circuit element mounting terminals 28a of the integrated circuit element 28 are electrically connected to the external portion mounting terminals 26a of the first sealing member 26 by a solder or the like.

The integrated circuit element 28 is a plate member having a rectangular shape in a plan view that is a view in a perpendicular direction to a pair of principal surfaces thereof each having a largest area. It is desirable that the integrated circuit element 28 has a rigidity that allows largest deflection to be 5 μm or less in a state of being held at both ends in the longitudinal direction under application of a pressure generated during molding using resin. Therefore, for the integrated circuit element 28, a modulus of longitudinal elasticity of a material and a cross-sectional secondary moment in the Z-direction that is a direction of a plan view are set such that the integrated circuit element 28 has a higher rigidity than that of at least the first sealing member 26 of the first sealing member 26 and the second sealing member 27. In this embodiment, it is desirable that the integrated circuit element 28 has a thickness of 80 μm or more. The thickness of the integrated circuit element 28 is larger than the thickness of each of the first sealing member 26 and the second sealing member 27.

As illustrated in FIG. 12, a width X13 of the integrated circuit element 28 in the X-direction that is the longitudinal direction is smaller than a width X11 of an outer edge of the frame portion 24 in the X-direction and is larger than a width X12 of an inner edge of the frame portion 24, when viewed in the Z-direction. A width Y13 of the integrated circuit element 28 in the Y-direction that is a perpendicular direction to the X-direction is smaller than a width Y11 of the outer edge of the frame portion 24 in the Y-direction and is larger than a width Y12 of the inner edge of the frame portion 24 in the Y-direction, when viewed in the Z-direction. That is, the integrated circuit element 28 is smaller than the frame portion 24 and is larger than the opening of the frame portion 24. Thus, an outer edge portion of the integrated circuit element 28 is supported by the frame portion 24 of the piezoelectric vibration plate 23 via the first sealing member 26.

As illustrated in FIG. 8 and FIG. 13, the substrate 29 is an insulating substrate that electrically connects the oscillator 22 and the integrated circuit element 28 to each other with a wiring pattern (not illustrated) and forms the oscillator 22 and the integrated circuit element 28 as an integrated body. One of principal surfaces of the substrate 29 includes connection terminals 29b used for mounting the oscillator 22. The other one of the principal surfaces of the substrate 29 includes substrate mounting terminals 29c provided for mounting the substrate 29 on an external substrate (see FIG. 13). The connection terminals 29b are electrically connected to the substrate mounting terminals 29c. Except for the foregoing, the configuration of the substrate 29 is approximately identical to the configuration of the substrate 11 of the first embodiment, and therefore, description thereof will be omitted.

The oscillator 22 on which the integrated circuit element 28 is mounted is mounted on a mounting surface 29a. The oscillator 22 is arranged on the substrate 29 such that the second sealing member 27 is opposed to the mounting surface 29a. Each of the oscillator mounting terminals 27a of the second sealing member 27 is electrically connected to the corresponding one of the connection terminals 29b of the mounting surface 29a via a solder or the like. Each of the integrated circuit element mounting terminals 28a of the integrated circuit element 28 is electrically connected to a circuit of the mounting surface 29a of the substrate 29 via a wire 28b.

The oscillator 22 mounted on the substrate 29 and the integrated circuit element 28 that is an electronic component element are electrically connected to the external substrate from the oscillator mounting terminals 27a via an unillustrated wiring pattern and the substrate mounting terminals 29c of the substrate 29. The vibrating portion 25 of the oscillator 22 oscillates at a predetermined frequency by a voltage applied from the external substrate.

The unillustrated molding portion protects the substrate 29 and at least the oscillator 22 of the oscillator 22 and the integrated circuit element 28 mounted on the substrate 29 with epoxy resin. The molding portion is similar to the molding portion 12 in the first embodiment, and therefore, description thereof will be omitted.

Next, with reference to FIG. 13, a state of the first sealing member 26 when the oscillator 22 and the substrate 29 are covered by the unillustrated molding portion will be described.

As illustrated in FIG. 13, in a case where the oscillator 22 and the substrate 29 are molded with the unillustrated epoxy resin, while the epoxy resin is being injected, a molding pressure is applied to the oscillator 22 and the integrated circuit element 28 from the Z-direction that is perpendicular to a contact surface with the epoxy resin (see arrows). A portion of the first sealing member 26 that covers the opening of the piezoelectric vibration plate 23 is covered by the integrated circuit element 28. Accordingly, when viewed in the Z-direction, a molding pressure given to the portion of the first sealing member 26 that covers the opening of the piezoelectric vibration plate 23 is applied to the integrated circuit element 28. The integrated circuit element 28 has a both-end supported structure in which the outer edge portion is supported by the frame portion 24. Therefore, with the first sealing member 26 covered by the integrated circuit element 28, an amount of deflection of the first sealing member 26 that covers the opening of the piezoelectric vibration plate 23 can be suppressed. Accordingly, the first sealing member 26 does not contact the vibrating portion 25 even when the first sealing member 26 is deflected in the Z-direction by the molding pressure. As described above, the integrated circuit element 28 has a function as a protecting member that covers the first sealing member 26 such that a molding pressure is not applied to the first sealing member 26.

In the piezoelectric vibration device 21 configured in a manner described above, the oscillator 22 having a three-layer structure, in which the piezoelectric vibration plate 23 is covered by the first sealing member 26 and the second sealing member 27, and the integrated circuit element 28 are mounted on the mounting surface 29a of the substrate 29. The piezoelectric vibration device 21 is configured such that at least the oscillator 22 is covered by the epoxy resin. The oscillator 22 is configured such that the first sealing member 26 closing the opening the frame portion 24 in the piezoelectric vibration plate 23 is covered by the integrated circuit element 28.

Therefore, the epoxy resin forming the molding portion does not contact the principal surface of the first sealing member 26 that is perpendicular to the Z-direction in a portion of the first sealing member 26 that covers the opening of the piezoelectric vibration plate 23. The integrated circuit element 28 covers the first sealing member 26 in a state where the peripheral edge thereof is supported by the frame portion 24. That is, the molding pressure of the epoxy resin applied to the integrated circuit element 28 is received by the frame portion 24. Thus, deflection of at least the first sealing member 26 of the first sealing member 26 and the second sealing member 27 can be suppressed during molding using epoxy resin.

### Variation of Second Embodiment

In the second embodiment described above, the integrated circuit element 28 as a protecting member is mounted on the principal surface of the first sealing member 26 of the oscillator 22 (see FIG. 13). However, as illustrated in FIG. 14, the oscillator 22 may be configured such that the integrated circuit element 28 is mounted on the protecting member 9 joined to the first sealing member 26. That is, the first sealing member 26 is protected from the molding pressure of the unillustrated molding portion by the protecting member 9. Accordingly, in the piezoelectric vibration device 21, the integrated circuit element 28 having an arbitrary size can be mounted on the oscillator 22. The protecting member 9 may include an electrically connecting portion, such as a wiring pattern or a through hole, and thus, be configured to be electrically connected to the oscillator 22.

### Third Embodiment

### <Configuration of Piezoelectric Vibration Device 41>

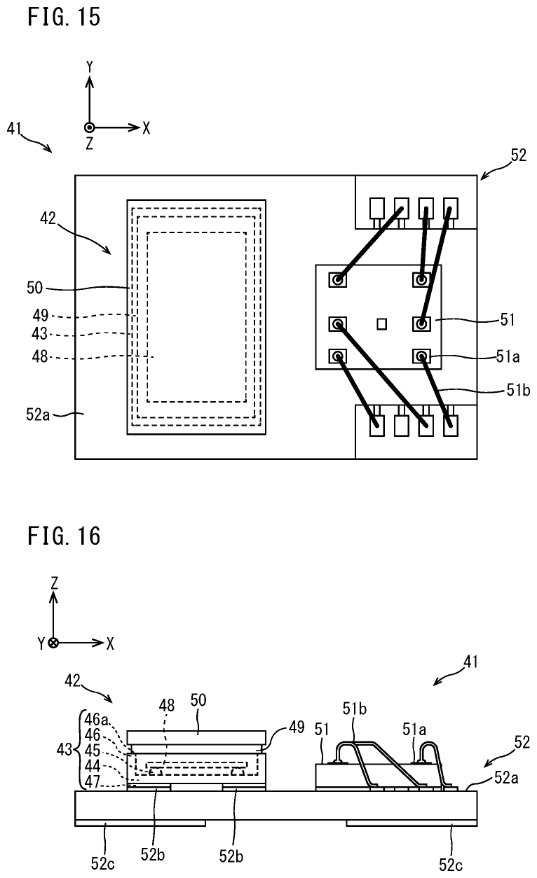

With reference to FIG. 15 and FIG. 16, a piezoelectric vibration device 41 that is a third embodiment of the present invention will be described. FIG. 15 is a plan view illustrating an outline of a whole configuration of the piezoelectric vibration device 41. FIG. 16 is a side view illustrating the outline of the whole configuration of the piezoelectric vibration device 41.

As illustrated in FIG. 15 and FIG. 16, the piezoelectric vibration device 41 includes an oscillator 42, an integrated circuit element 51, a substrate 52, and a molding portion (not illustrated).

The oscillator 42 includes a holding member 43, a piezoelectric element 48, a sealing member 49, and a protecting member 50.

The holding member 43 is a box-shaped container that is formed of an insulator and holds the piezoelectric element 48. In this embodiment, the holding member 43 is a ceramic housing. The holding member 43 is formed of sintering ceramic powder. The holding member 43 may be formed by stacking a plurality of insulators. The holding member 43 includes a bottom portion 44, electrode pads 45, a frame portion 46, and external terminals 47.

The bottom portion 44 forms a bottom surface of the holding member 43. The bottom portion 44 is formed of a rectangular plate member. The electrode pad 45 that is conductive metal is formed along a short side of the rectangular plate member on an upper surface of the bottom portion 44 that is one surface of the bottom portion 44. The electrode pad 45 is electrically connected to the piezoelectric element 48. The electrode pad 45 is a portion of an electric circuit that applies a voltage to the piezoelectric element 48. The external terminal 47 that is conductive metal is deposited on a lower surface that is the other surface of the bottom portion 44. The external terminal 47 is electrically connected to the substrate 52. The external terminal 47 is used for transmitting a signal from the substrate 52 to the piezoelectric element 48 and applying a voltage. The electrode pad 45 and the external terminal 47 are electrically connected to each other via an unillustrated wiring pattern.

The frame portion 46 forms a side surface of the holding member 43. The frame portion 46 is arranged at an outer edge of the bottom portion 44. The frame portion 46 is a frame-shaped wall surrounding the bottom portion 44. The frame portion 46 extends upward from the upper surface of the bottom portion 44. The frame portion 46 has a predetermined thickness from an outer surface to an inner surface. An upper edge portion of the frame portion 46 has a joined surface 46a joined to the sealing member 49. In the holding member 43 configured in a manner described above, an internal space that accommodates the piezoelectric element 48 is formed by the upper surface of the bottom portion 44 and the inner surface of the frame portion 46. The holding member 43 is opened upward from the upper surface of the bottom portion 44. The electrode pad 45 is arranged in the internal space.

The piezoelectric element 48 that is a vibrating portion is a piezoelectric body that converts an applied force to a voltage or converts an applied voltage to a force. In this embodiment, the piezoelectric element 48 is a rectangular crystal vibration piece (for example, an AT-cut crystal piece) that is crystal cut out in a specific direction. In the piezoelectric element 48, unillustrated electrodes are deposited on both a pair of principal surfaces thereof each having a largest area. The piezoelectric element 48 is arranged in the internal space of the holding member 43. The electrodes of the piezoelectric element 48 are bonded to the electrode pad 45 of the holding member 43. Thus, the piezoelectric element 48 can be electrically connected to the substrate 52 from the electrodes via the electrode pad 45, the unillustrated wiring pattern, and the external terminal 47. The piezoelectric element 48 is held so as to be held in a cantilever-supported state by the holding member 43. Thus, the piezoelectric element 48 oscillates at a predetermined frequency by a voltage applied from the external substrate.

The sealing member 49 is a lid member that makes the internal space of the holding member 43 into a sealed space. The sealing member 49 is formed of a metal material, such as, for example, kovar. For example, electrolytic nickel plating, non-electrolytic nickel plating, or the like is performed on the sealing member 49. The sealing member 49 is arranged in the upper edge portion of the holding member 43 such that a lower surface of the sealing member 49 that is one surface thereof is opposed to the holding member 43. The sealing member 49 has a size large enough to cover an opening of the holding member 43 when viewed in the Z-direction, that is, in a plan view. The sealing member 49 is smaller than the holding member 43 when viewed in the Z-direction. A frame-shaped sealing material is provided in a portion of the holding member 43 that overlaps the joined surface 46a of the frame portion 46 when viewed in the Z-direction. The sealing member 49 is joined to the joined surface 46a of the frame portion 46. Thus, the piezoelectric element 48 is hermetically sealed in the internal space of the holding member 43 by the sealing member 49.

The protecting member 50 suppresses deflection of the sealing member 49 caused by a molding pressure of resin forming the unillustrated molding portion. A configuration of the protecting member 50 is identical to the configuration of the protecting member 9 of the first embodiment, and therefore, description thereof will be omitted. The protecting member 50 is formed to have approximately the same size as the holding member 43 when viewed in the Z-direction. The protecting member 50 is joined to a perpendicular surface of the sealing member 49 to the Z-direction by a thermoplastic additive or a die attach agent that is a joining material. The protecting member 50 entirely covers the sealing member 49 including a portion overlapping the opening in the Z-direction.

The integrated circuit element 51 is an IC that controls the oscillator 42. A configuration of the integrated circuit element 51 is identical to the configuration of the integrated circuit element 10 of the first embodiment, and therefore, description thereof will be omitted. The integrated circuit element 51 outputs an oscillation output generated by an oscillation circuit as a reference signal, such as a clock signal, to outside through integrated circuit element mounting terminals 51a.

The substrate 52 is an insulating substrate that electrically connects the oscillator 42 and the integrated circuit element 51 to each other with a wiring pattern (not illustrated) and forms the oscillator 42 and the integrated circuit element 51 as an integrated body. One of principal surfaces of the substrate 52 is configured as a mounting surface 52a including connection terminals 52b provided for mounting the oscillator 42. Each of the integrated circuit element mounting terminals 51a of the integrated circuit element 51 is electrically connected to a circuit of the mounting surface 29a of the substrate 52 via a wire 51b. The other one of the principal surfaces of the substrate 52 includes substrate mounting terminals 52c used for mounting the substrate 52 on an external substrate. Except for the foregoing, a configuration of the substrate 52 is approximately identical to the configuration of the substrate 11 of the first embodiment, and therefore, description thereof will be omitted.

The unillustrated molding portion protects the substrate 52 and at least the oscillator 42 of the oscillator 42 and the integrated circuit element 51 mounted on the substrate 52 with epoxy resin. The molding portion is similar to the molding portion 12 of the first embodiment, and therefore, description thereof will be omitted.

In a case where the oscillator 42 and the substrate 52 are molded with unillustrated epoxy resin, a molding pressure applied to the oscillator 42 is applied to the protecting member 50 that covers the sealing member 49 of the oscillator 42. Accordingly, with the sealing member 49 covered by the protecting member 50, an amount of deflection of the sealing member 49 that covers the opening of the holding member 43 can be suppressed. Therefore, the sealing member 49 does not contact the piezoelectric element 48 even when the sealing member 49 is deflected in the Z-direction by the molding pressure.

### Other Embodiments

In the first embodiment described above, the resin film forming each of the first sealing member 7 and the second sealing member 8 is a polyimide resin film. However, each of the first sealing member and the second sealing member is not limited to a film formed of polyimide resin, but a film formed of a resin that is classified as super engineering plastic, such as, for example, polyamide resin and polyetheretherketone resin may be used.

In the embodiment described above, the protecting member 9 is formed of silicon. However, the protecting member may be formed of glass, crystal, quarts, ceramic, or the like that is a brittle material, alumina that is a ductile material, or the like. Each of the protecting members 9 and 50 and the integrated circuit element 28 may be provided to partially or entirely cover the sealing member.

In the first embodiment described above, the peripheral edge of the protecting member 9 is located more inside than the outer peripheral edge of the frame portion 4 of the piezoelectric vibration plate 3. However, the peripheral edge of the protecting member may be located more outside than the outer peripheral edge of the frame portion of the piezoelectric vibration plate.

In the first embodiment described above, the peripheral edge of the first sealing member 7 is located more inside than the outer peripheral edge of the piezoelectric vibration plate 3 and the peripheral edge of the protecting member 9. However, the first protecting member may be located more outside than the outer peripheral edge of the piezoelectric vibration plate and the peripheral edge of the protecting member.

In the embodiments described above, each of the substrates 11 and 29 is formed of glass polyimide resin. However, a glass composite substrate of glass epoxy resin or the like, a fluororesin substrate, a ceramic substrate, or the like may be used for the substrate.

In the embodiments described above, each of the piezoelectric vibration devices 1 and 21 includes a corresponding one of the oscillators 2 and 22 having a three-layer structure in which a corresponding one of the piezoelectric vibration plates 3 and 23, a corresponding one of the first sealing members 7 and 26, and a corresponding one of the second sealing members 8 and 27 are stacked. However, the piezoelectric vibration device may include an oscillator having a multi-layer structure including three or more layers. The oscillator may be a four-layer oscillator in which a sensor, such as a thermistor, is further mounted on the principal surface of the first sealing member.

In the third embodiment described above, the oscillator 42 includes the piezoelectric element 48 formed of a rectangular crystal vibration piece (for example, an AT-cut crystal piece) serving as a vibrating portion. However, the oscillator is not limited to an AT-cut crystal plate, but may be a crystal vibration plate having some other cut angle than that of an AT-cut, such as a tuning fork crystal vibration plate or an SC-cut crystal vibration plate, including a vibrating portion therein.

In the first embodiment described above, the piezoelectric vibration device 1 is configured such that the vibrating portion 5 or 17 is arranged in the internal space S of the piezoelectric vibration plate 3. However, the piezoelectric vibration device may be a piezoelectric vibration device having a so-called H-shaped structure that includes a bottom portion and frame-shaped side wall portions each being formed on a corresponding one of two opposed plane surfaces of the bottom portion to extend in a perpendicular direction to the plane surface. In the piezoelectric vibration device having the H-shaped structure, a piezoelectric element is arranged at an inner side of one of the side wall portions on one of the plane surfaces of the bottom portion. Moreover, in the piezoelectric vibration device having the H-shaped structure, an electronic component element is mounted at an inner side of the other one of the side wall portions on the other one of the plane surfaces of the bottom portion. The piezoelectric vibration device having the H-shaped structure is configured such that a first sealing member is joined to a tip end portion of the one of the side wall portions and a second sealing member is joined to a tip end portion of the other one of the side wall portions.

In the second embodiment described above, the thickness of the vibrating portion 25 arranged in the frame portion 24 is smaller than the thickness of the frame portion 24. However, the vibrating portion may have the same thickness as the frame portion. In this case, each of the first sealing member and the second sealing member that are joined to the frame portion has a recessed portion in a principal surface opposed to the vibrating portion. Thus, the oscillator is configured such that gaps are formed between the first sealing member and the vibrating portion and between the second sealing member and the vibrating portion.

In the second embodiment described above, the integrated circuit element 28 is joined onto the first sealing member 26 by a solder. However, the integrated circuit element may be joined to the first sealing member by a die attach tape, a conductive adhesive, or the like.

In the embodiments described above, the integrated circuit elements 10, 28, and 51 that have an oscillation circuit element that is an electronic component element for controlling an oscillator are mounted on the substrates 11, 29, and 52, respectively. The integrated circuit element 28 that is an electronic component element is mounted as a protecting member on the oscillator 22. However, electronic component elements mounted on the substrate and the oscillator may be electronic components, such as an oscillation circuit element thermistor or various types of sensors.

Embodiments of the present invention have been described above, but the above-described embodiments are merely illustrative examples for carrying out the present invention. Therefore, the present invention is not limited to the above-described embodiments and the above-described embodiments can be appropriately modified and implemented without departing from the gist of the present invention.

### REFERENCE SIGNS LIST

1, 21, 41 Piezoelectric vibration device
2, 14, 22, 42 Oscillator
3, 15, 23 Piezoelectric vibration plate
4, 16, 24, 46 Frame portion
16e, 16f Recessed portion
4a First joined surface
4b Second joined surface
46a Joined surface
4c, 23a Through portion
4d, 16d, 27a Oscillator mounting terminal
5, 17, 25 Vibrating portion
5a First excitation electrode
5b Second excitation electrode
6 Connecting portion
25a Pair of excitation electrodes
7, 26 First sealing member
26a External portion mounting terminal
8, 27 Second sealing member
27a Oscillator mounting terminal
9, 50 Protecting member
10, 28, 51 Integrated circuit element
10a, 28a, 51a Integrated circuit element mounting terminal
10b, 28b, 51b Wire
11, 29, 52 Substrate
11a, 29a, 52a Mounting surface
29b, 52b Connection terminal
11b, 29c, 52c Substrate mounting terminal
12 Molding portion
13, 23b Joining material
43 Holding member
48 Piezoelectric element
49 Holding member
S Internal space
G Gap

1. A piezoelectric vibration device comprising:
an oscillator configured such that at least a vibrating portion is sealed with a sealing member;
at least an electronic component element;
a substrate including a mounting surface on which the oscillator and the electronic component element are mounted; and
a molding portion in which at least the oscillator is covered with resin,
wherein
the oscillator includes a protecting member that covers at least a portion of the sealing member.

2. The piezoelectric vibration device according to claim 1,
wherein
the oscillator is configured into a stacked body with three or more layers, the stacked body including
a piezoelectric vibration plate configured such that a frame portion and the vibrating portion arranged inside a frame of the frame portion are integrally molded and
the sealing members each being joined to a corresponding one of one and the other one of principal surfaces of the frame portion in the piezoelectric vibration plate to close a corresponding one of an opening of the one of the principal surfaces and an opening of the other one of the principal surfaces, and
at least one of the sealing members that close the opening of the one of the principal surfaces and the opening of the other one of the principal surfaces is partially or entirely covered by the protecting member.

3. The piezoelectric vibration device according to claim 1,
wherein
the oscillator includes at least
a piezoelectric element including the vibrating portion,
a box-shaped holding member configured such that one of principal surfaces thereof is opened to form a frame portion, and
the sealing member that closes an opening of the holding member that holds the piezoelectric element inside the frame portion, and
the sealing member is partially or entirely covered by the protecting member.

4. The piezoelectric vibration device according to claim 2,
wherein
the oscillator is configured such that
a portion of the vibrating portion is connected to the frame portion via a connecting portion, and
the sealing member is a resin film.

5. The piezoelectric vibration device according to claim 2,
wherein
the oscillator includes a recessed portion in one or both of one and the other one of principal surfaces of the piezoelectric vibration plate, and
the recessed portion serves as the vibrating portion.

6. The piezoelectric vibration device according to any one of claims 1 to 5,
wherein
the oscillator and the electronic component element are arranged on the same mounting surface of the substrate.

7. The piezoelectric vibration device according to any one of claims 2 to 6,
wherein
the protecting member is configured such that at least a portion thereof overlaps the frame portion when viewed in a perpendicular direction to the principal surfaces.

8. The piezoelectric vibration device according to any one of claims 2 to 7,
wherein
the oscillator is configured such that a peripheral edge of the sealing member is located more inside than an outer peripheral edge of the frame portion and a peripheral edge of the protecting member is located more outside than the peripheral edge of the sealing member.

9. The piezoelectric vibration device according to any one of claims 1 to 8,
wherein
the protecting member is thicker than the sealing member.

10. The piezoelectric vibration device according to any one of claims 1 to 9,
wherein
the substrate is formed of a resin material.

11. The piezoelectric vibration device according to any one of claims 1 to 10,
wherein
the protecting member is formed of a brittle material.

12. The piezoelectric vibration device according to any one of claims 1 to 11,
wherein
the protecting member is joined to the sealing member via a joining material.

13. The piezoelectric vibration device according to any one of claims 1 to 12,
wherein
the electronic component element is at least an integrated circuit element including an oscillation circuit element of the oscillator.

14. The piezoelectric vibration device according to any one of claims 1 to 13,
wherein
the protecting member is configured of an electronic component element.
